(19) United States
(12) Patent Application Publication
(10) Pub. No.: US 2009/0004839 A1
(43) Pub. Date: Jan. 1, 2009

(54) METHOD FOR FABRICATING AN INTERLAYER DIELECTRIC IN A SEMICONDUCTOR DEVICE

(75) Inventor: Byung Soo EUN, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/145,336

(22) Filed: Jun. 24, 2008

(30) Foreign Application Priority Data
Jun. 28, 2007 (KR) 10-2007-0064761
Mar. 27, 2008 (KR) 10-2008-0028629

(51) Int. Cl. H01L 21/44

(52) U.S. Cl. 438/597; 257/E21.507

(57) ABSTRACT

In a method for fabricating an interlayer dielectric in a semiconductor device, conductive patterns are formed on a semiconductor substrate. A fluid dielectric is formed to cover the conductive patterns. The fluid dielectric is recessed. A buried dielectric is deposited on the conductive patterns exposed by the recessing process. The buried dielectric is denser than the fluid dielectric, thereby forming an interlayer dielectric including the fluid dielectric and the buried dielectric.

### CROSS-REFERENCE TO RELATED APPLICATIONS

The present application claims priority to Korean patent application number 10-2007-0064761, filed on Jun. 28, 2007, and Korean patent application number 10-2008-0028629, filed on Mar. 27, 2008, both of which are incorporated by reference in their entirety.

### BACKGROUND OF THE INVENTION

The present invention relates to a semiconductor device, and more particularly, to a method for fabricating an interlayer dielectric in a semiconductor device.

In a fabrication process of a highly integrated device, a critical dimension (CD) of a bit line stack is becoming increasingly reduced. Due to the reduction in the CD of the bit line stack, a CD of a spacer disposed between bit line stacks is also reduced. Thus, there is a limitation in a high density plasma (HDP) process that has been used as a gap-fill process. One of problems occurring in a conventional gap-fill process is a phenomenon that bends bit line stacks.

FIG. 1 illustrates a cross-sectional view of a typical bit line stack, and FIGS. 2 to 4 illustrates defects occurring in the bit line stack.

Referring to FIG. 1, a bit line stack 120 is formed on a semiconductor substrate 100, and an interlayer dielectric 125 is formed to cover the bit line stack 120. The bit line stack 120 has a stacked structure of a barrier metal layer 105, a bit line metal layer 110, and a hard mask layer 115. The interlayer dielectric 125 covering the bit line stack 120 is generally formed using an HDP process. However, if the interlayer dielectric 125 is formed using the HDP process, a bending phenomenon occurs and the bit line stack 120 is bent in one direction. The bending phenomenon is generated when a different amount of charges are applied to the left and right of the bit line stack 120 during the HDP process such that an attractive force is unequally applied to one side of the bit line stack 120. The bending phenomenon may be caused by damage due to plasma applied during the HDP process. Due to these limitations in the fabrication process, a method for covering the bit line stack with a single-layered fluid dielectric has been proposed and applied. The fluid dielectric was developed as a device isolation material. Many studies have been conducted to use the fluid dielectric in a micro or sub-micro device, for example, a gate stack or a bit line stack requiring a gap-fill process.

As the integration density of a semiconductor device increases, the semiconductor device shrinks in size. Hence, even though the interlayer dielectric is formed using the single-layered fluid dielectric, the bending phenomenon bends the bit line stack 120. The bending phenomenon may be caused by a large height difference of the bit line stack 120 due to the high integration density of the semiconductor device and by a soft layer quality of the fluid dielectric. In particular, if an amorphous carbon layer is deposited on the fluid dielectric in order to perform a subsequent process for forming a storage node contact hole, a crack may be formed between the bit line stack and the fluid dielectric due to a remaining tensile stress of the fluid dielectric. A crack (A) formed in the fluid dielectric 127 can be observed from FIG. 2. If a subsequent process is performed in such a state that the crack A is formed, the bit line stack 120 does not endure a thermal treatment and a self align contact (SAC) process, and becomes bent in one direction. If a subsequent process is performed in such a state, storage node contact holes 300 are not formed, as indicated by a reference symbol “B” in FIG. 3. In addition, as illustrated in FIG. 4, a bunker defect C may be generated during a process of forming a storage node. FIG. 4 illustrates a semiconductor 400, a word line 410, a bit line stack 420. If a mask misalignment occurs in forming a capacitor in such a state that the crack is formed in the fluid dielectric, the bunker defect C is generated because a chemical solution penetrates into the crack and, thus, the fluid dielectric having a fast etching rate is dipped out. However, an internal control for the crack defect is difficult and the detection of the crack defect is also difficult. Thus, the crack defect causes a lot of problems in the fabrication process.

### SUMMARY OF THE INVENTION

In one embodiment, a method for fabricating an interlayer dielectric in a semiconductor device includes: forming conductive patterns on a semiconductor substrate; forming a fluid dielectric covering the conductive patterns; recessing the fluid dielectric; and depositing a buried dielectric on the conductive patterns exposed by the recessing process. The buried dielectric is relatively denser than the fluid dielectric, thereby forming an interlayer dielectric including the fluid dielectric and the buried dielectric.

The method may further include planarizing the recessed fluid dielectric by a chemical mechanical polishing (CMP) process.

The fluid dielectric may be formed of polysilazane (PSZ) based spin on dielectric (SOD).

The fluid dielectric may be recessed until a portion of a sidewall of the conductive pattern is exposed.

The depositing of the buried dielectric may include: depositing a seed layer along the fluid dielectric exposed by the recessing process and a portion of a sidewall of the conductive pattern; forming a high density plasma (HDP) oxide layer on the seed layer by supplying an HDP deposition source; etching an overhang formed on a top portion of the bit line stack when forming the HDP oxide layer; and burying the bit line stack by additionally performing the process of forming the HDP oxide layer and the process of etching the overhang.

The HDP deposition source may include silane (SiH4) gas, oxygen (O2) gas, and helium (He) gas. The overhang formed on the top portion of the bit line stack may be etched using a fluorine (F) based etching gas including nitrogen trifluoride (NF3) gas.

The method may further include performing a preheating process before forming the seed layer. The performing of the preheating process may include: loading the semiconductor substrate within an HDP chamber; and supplying oxygen (O2) gas, argon (Ar) gas, and helium (He) gas and supplying bias to the top and side of the HDP chamber. The process of forming the HDP oxide layer and the process of etching the overhang may be performed for 4-10 cycles.

The buried dielectric prevents bending of the bit line stacks and fixes locations of the bit line stacks.

In another embodiment, a method for fabricating an interlayer dielectric in a semiconductor device includes: forming bit line stacks on a semiconductor substrate; forming a fluid dielectric on the bit line stacks; recessing the fluid dielectric; forming a seed layer along the fluid dielectric exposed by the recessing process and a portion of sidewalls of the bit line stacks; forming a first HDP oxide layer on the seed layer by supplying an HDP deposition source including silane (SiH4) gas, oxygen (O2) gas, and helium (He) gas; etching an overhang formed on top portions of the bit line stacks by supplying an etching gas to the first HDP oxide layer; and forming an interlayer dielectric including the fluid dielectric and a second HDP oxide layer. The second HDP oxide layer is formed to cover the bit lines stacks by additionally performing the process of forming the first HDP oxide layer and the process of etching the overhang.

In still another embodiment, a method for fabricating an interlayer dielectric in a semiconductor device includes: forming bit line stacks on a semiconductor substrate; forming a fluid dielectric on the bit line stacks; planarizing the fluid dielectric to expose top surfaces of the bit line stacks; and forming a capping layer on the bit line stacks and the fluid dielectric. Top surfaces of the bit line stacks and the fluid dielectric are exposed by the planarization process. The capping layer is denser than the fluid dielectric.

### BRIEF DESCRIPTION OF THE DRAWINGS

FIG. 1 illustrates a cross-sectional view of a typical bit line stack.

FIGS. 2 to 4 illustrate defects occurring in the bit line stack.

FIGS. 5 to 13 illustrate a method for fabricating an interlayer dielectric in a semiconductor device according to an embodiment of the present invention.

FIG. 14 illustrates an HDP chamber which is applied to the embodiments of the present invention.

FIGS. 15 to 25 illustrate a method for fabricating an interlayer dielectric of a semiconductor device according to another embodiment of the present invention.

FIGS. 26 to 29 illustrate a method for fabricating an interlayer dielectric of a semiconductor device according to still another embodiment of the present invention.

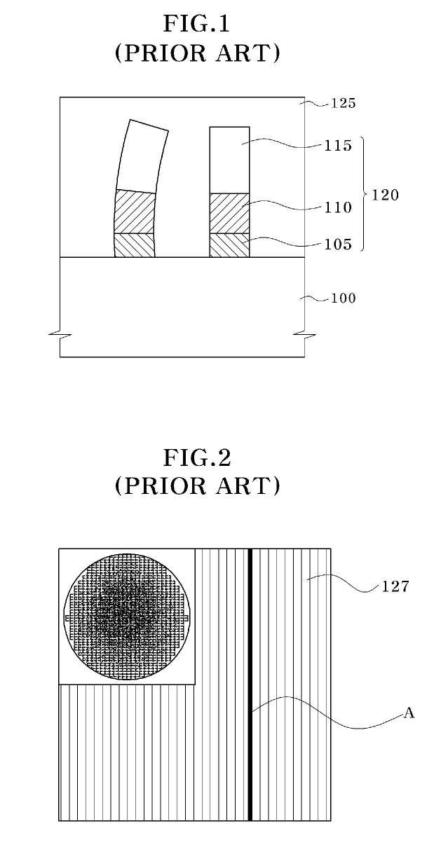

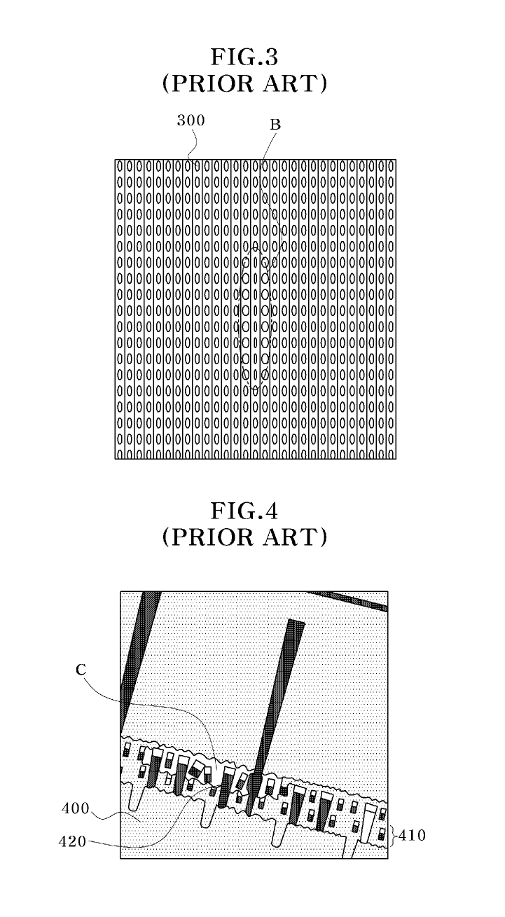

### DESCRIPTION OF SPECIFIC EMBODIMENTS

Hereinafter, a method for fabricating an interlayer dielectric in a semiconductor device in accordance with the present invention will be described in detail with reference to the accompanying drawings.

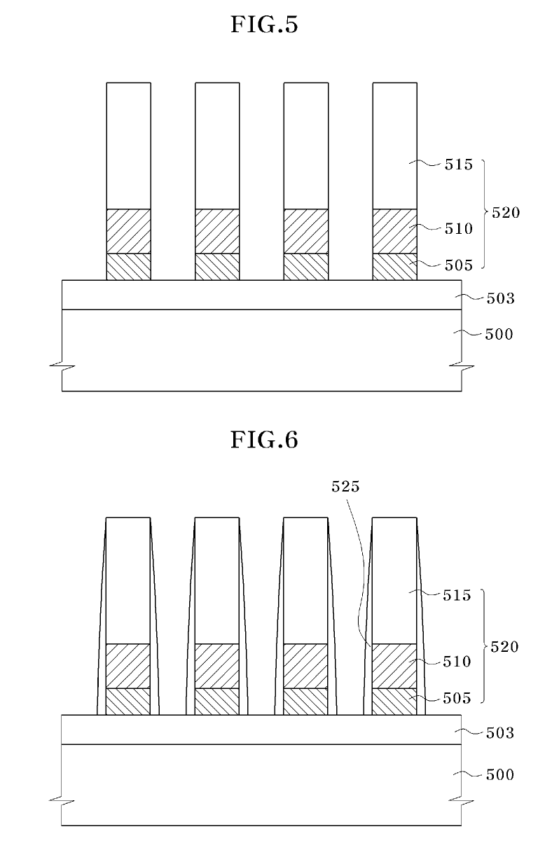

FIGS. 5 to 13 illustrate a method for fabricating an interlayer dielectric in a semiconductor device according to an embodiment of the present invention.

Referring to FIG. 5, bit line stacks 520 are formed on a semiconductor substrate 500. Specifically, a barrier metal layer, a bit line conductive layer, and a hard mask layer are deposited on the semiconductor substrate 500. The barrier metal layer may include a metal film containing titanium (Ti), and the bit line conductive layer may include a tungsten (W) film. The hard mask layer may include a nitride film. An interlayer dielectric 503 having a lower structure (not shown) with a word line is formed on the semiconductor substrate 500. Hard mask patterns 515 are formed by patterning the hard mask layer. Bit line stacks 520 including barrier metal patterns 505, bit line conductive patterns 510, and hard mask patterns 515 are formed by etching the lower layers, for example the bit line conductive layer and the barrier metal layer, using the hard mask patterns 515 as an etch mask. As the semiconductor device is highly integrated, the bit line stack 520 has an aspect ratio of 5:1.

Referring to FIG. 6, bit line spacers 525 are formed on sidewalls of the bit line stacks 520. The bit line spacers 525 may be formed by depositing a spacer layer on the semiconductor substrate 500, where the bit line stacks 520 are formed, and performing an etch back process on the deposited spacer layer.

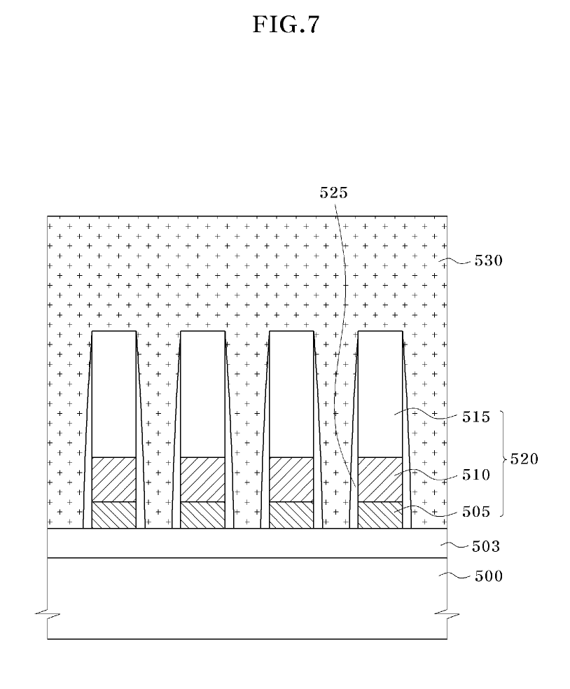

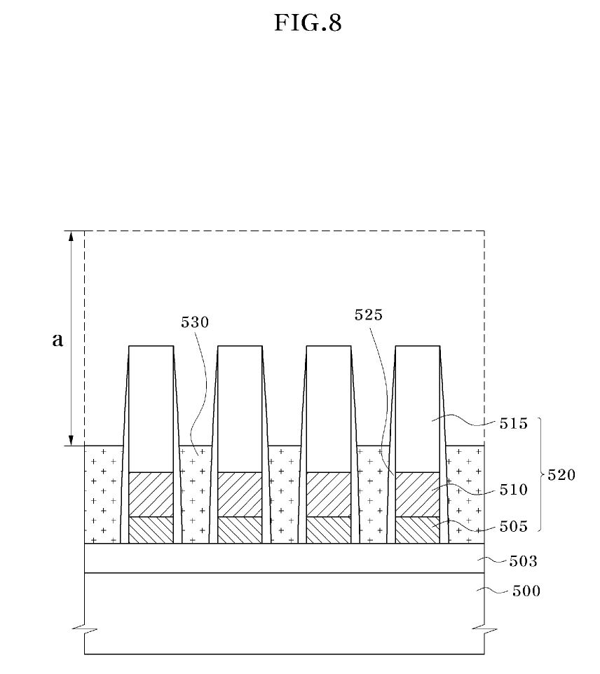

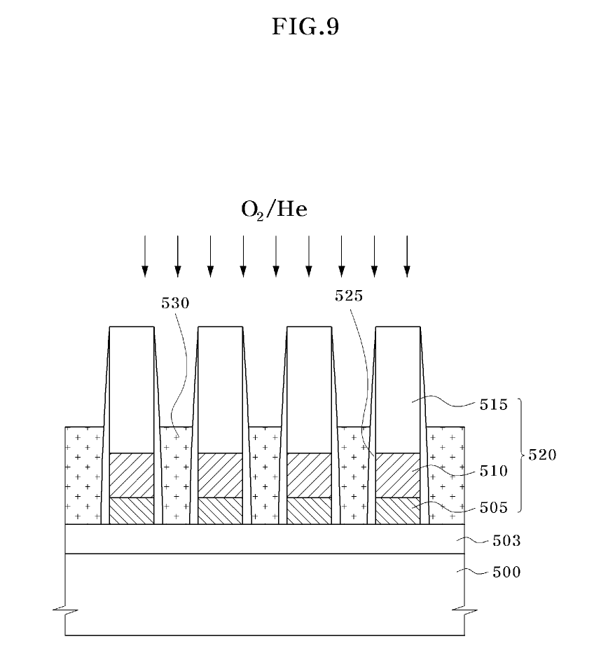

Referring to FIG. 7, a fluid dielectric 530 covering the bit line stacks 520 is formed on the semiconductor substrate 500. The fluid dielectric 530 is formed by spin-coating a spin on dielectric (SOD). Since the SOD has an excellent gap-fill characteristic, it is used as a gap-fill material in a region where a gap between patterns is narrow. The SOD is formed of a polysilazane (PSZ) based SOD. The fluid dielectric may be formed of a spin on glass (SOG) containing hydrogen silsequioxane (HSQ). However, in the case of the SOG containing HSQ, excessive shrinkage occurs during a curing process and, thus, a void is formed within the fluid dielectric. Since the PSZ compound shrinks slightly during a curing process, a void is not formed. Therefore, it is preferable that the fluid dielectric 530 is formed of the SOD containing PSZ instead of SOG.

The semiconductor device is heated at approximately 130° C. to approximately 150° C. for approximately 150 seconds to approximately 200 seconds, thereby evaporating a solvent from the fluid dielectric 530. A curing process is performed on the fluid dielectric 530. The curing process is performed for approximately 1 hour while supplying 1 L hydrogen (H₂) gas and 2 L oxygen (O₂) at a temperature of approximately 450° C. to approximately 550° C. The curing process changes the fluid dielectric 530 into an oxide layer. The fluid dielectric 530 is planarized by a planarization process, for example, a chemical mechanical polishing (CMP) process. The planarization process is performed on the fluid dielectric 530 in a subsequent process. The planarization process is performed until the fluid dielectric 530 has a thickness of 450 Å to 550 Å from the hard mask pattern 515 of the bit line stack 520.

Referring to FIG. 8, the planarized fluid dielectric 530 is recessed to a predetermined depth (a) from the deposition surface, so that a portion of the side surface of the spacer layer 525 of the bit line stack 520 is exposed. The process of recessing the fluid dielectric 530 is performed by a wet etching process using hydrogen fluoride (HF) aqueous solution in which water (H₂O) and hydrogen fluoride (HF) are mixed at a volume ratio of 100:1. The fluid dielectric 530 is recessed to a predetermined depth (a) from the top surface of the fluid dielectric 530, for example a thickness of approximately 900 Å to approximately 1,100 Å, so that a portion of the side surface of the spacer layer 525 of the bit line stack 520 is exposed.

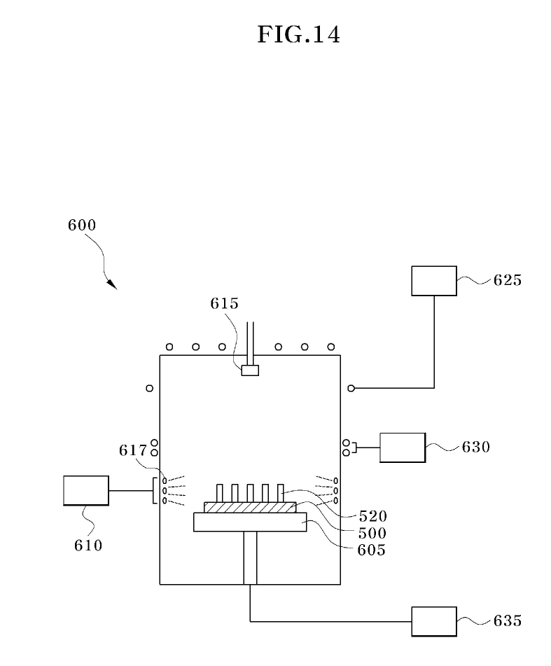

Referring to FIGS. 9 and 14, the semiconductor substrate 500 with the recessed fluid dielectric 530 is preheated in an atmosphere containing oxygen (O₂) gas and helium (He) gas. Specifically, the semiconductor substrate 500 is loaded onto a stage 605 of an HDP chamber 600 as illustrated in FIG. 14. Oxygen (O₂) gas and argon (Ar) gas are supplied as a source gas from a gas tank 610 to the HDP chamber 600 through gas supply nozzles 615 and 617, and helium (He) gas is supplied as an additive gas. Power is supplied from bias supply units 625, 630 and 635 and preheating is performed for 20-30 seconds. The oxygen (O₂) gas is supplied at a flow rate of approximately 50 sccm to approximately 150 sccm, the argon (Ar) gas is supplied at a flow rate of approximately 40 sccm to approximately 50 sccm, and the helium (He) gas is supplied at a flow rate of approximately 200 sccm to approximately 300 sccm. The helium (He) gas is additionally supplied from the top 615 of the HDP chamber 600 at a flow rate of approximately 200 sccm to approximately 300 sccm. As the source power for generating plasma, a top bias 625 of approximately 4,500 W to approximately 5,500 W is supplied, and a side bias 630 of approximately 3,500 W to approximately 4,500 W is supplied. However, a bottom bias 635 is not supplied.

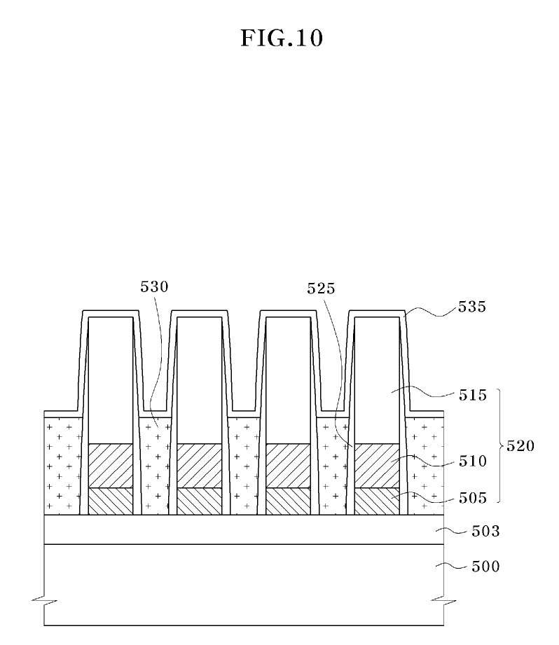

Referring to FIGS. 10 to 14, a seed layer 535 is formed on the exposed portions of the recessed fluid dielectric 530 and the bit line stack 520. The seed layer 535 serves as a seed of an HDP oxide layer, which will be formed later. The seed layer 535 is formed by supplying an HDP deposition source within the HDP chamber 600 where the preheating is performed. The HDP deposition source includes a source gas containing silane (SiH₄) gas and oxygen (O₂) gas, and an additive gas containing helium (He) gas. The oxygen (O₂) gas as the HDP deposition source is supplied at a flow rate of approximately 100 to approximately 120 sccm. The silane (SiH₄) gas is supplied from the top 615 of the HDP chamber 600 at a flow rate of approximately 25 sccm to approximately 35 sccm and is supplied from the side 617 of the HDP chamber 600 at a flow rate of approximately 40 sccm to approximately 55 sccm. The helium (He) gas as the additive gas is supplied from the top 615 of the HDP chamber 600 at a flow rate of approximately 50 sccm to approximately 150 sccm and is supplied from the side 617 of the HDP chamber 600 at a flow rate of approximately 150 sccm to approximately 250 sccm. In order to generate plasma, the top bias 625 of approximately 7,500 W to approximately 8,500 W is supplied, and the side bias 630 of approximately 4,500 W to approximately 5,500 W is supplied. In addition, the bottom bias 635 of approximately 450 W to approximately 500 W is supplied from the bottom of the HDP chamber 600. Due to the HDP deposition source and the biases supplied to the HDP chamber 600, the seed layer 535 is formed to a thickness of approximately 300 Å to approximately 400 Å along the exposed portions of the recessed fluid dielectric 530 and the bit line stack 520.

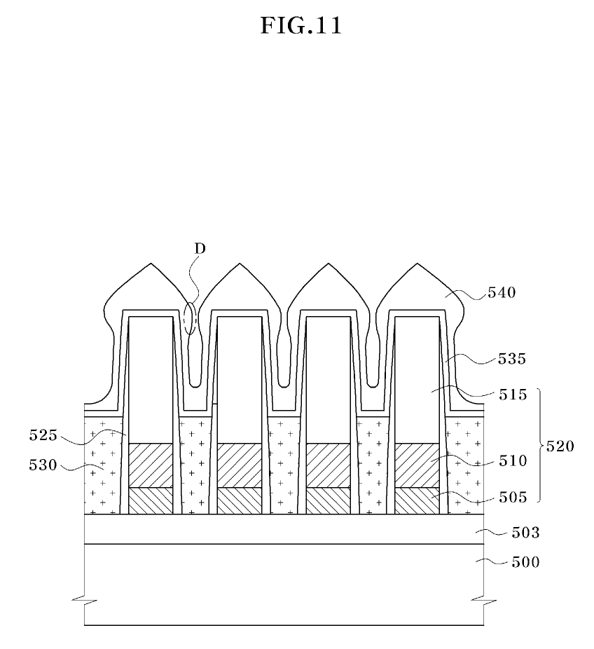

Referring to FIGS. 11 and 14, a first HDP oxide layer 540 is formed on the seed layer 535 to a thickness of approximately 500 Å to 900 Å by additionally supplying the HDP deposition source to the HDP chamber 600. As the HDP deposition source, the oxygen (O₂) gas is supplied at a flow rate of approximately 70 sccm to approximately 80 sccm. In addition, the silane (SiH₄) gas is supplied from the top 615 of the HDP chamber 600 at a flow rate of approximately 100 sccm to approximately 150 and is supplied from the side 617 of the HDP chamber 600 at a flow rate of approximately 40 sccm to approximately 50 sccm. As the additive gas, the helium (He) gas is supplied at a flow rate of approximately 250 sccm to approximately 350 sccm, and the hydrogen (H₂) gas is supplied at a flow rate of approximately 100 sccm to approximately 150 sccm. In order to generate plasma, the top bias 625 of approximately 6,500 W to approximately 7,500 W is supplied, and the side bias 630 of approximately 6,500 W to approximately 7,500 W is supplied. In addition, the bottom bias 635 of approximately 1,500 W to approximately 2,500 W is supplied from the bottom of the HDP chamber 600. The first HDP oxide layer 540 is formed on the seed layer 535 by the biases supplied to the HDP chamber 600 while supplying the HDP deposition source. In this case, due to a narrow gap between the bit line stacks 520, the deposition is quickly performed on the top portion, thereby forming an overhang D.

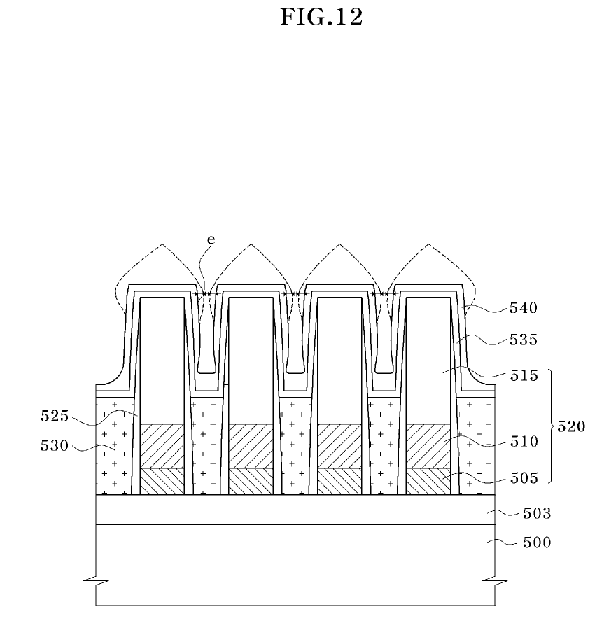

Referring to FIGS. 12 and 14, an etching process is performed to remove the overhang (D in FIG. 11) formed on the top portion of the bit line stack 520 by supplying an etching gas to the first HDP oxide layer 540. The etching gas uses fluorine (F) based gas, for example, nitrogen trifluoride (NF₃) gas. In addition, hydrogen (H₂) gas and helium (He) gas are supplied. The nitrogen trifluoride (NF₃) is supplied at a flow rate of approximately 100 sccm to approximately 200 sccm, and the hydrogen (H₂) gas is supplied at a flow rate of approximately 100 sccm to approximately 200 sccm. The helium (He) gas is supplied from the top 615 of the HDP chamber 600 at a flow rate of approximately 50 sccm to approximately 70 sccm and is supplied from the side 617 of the HDP chamber 600 at a flow rate of approximately 50 sccm to approximately 70 sccm. The process of etching the overhang is performed while adjusting an etch target (e) to a thickness of approximately 150 Å to approximately 250 Å. While forming the first HDP oxide layer 540, the overhang formed on the top portion of the bit line stack 520 is etched thereby securing a deposition space.

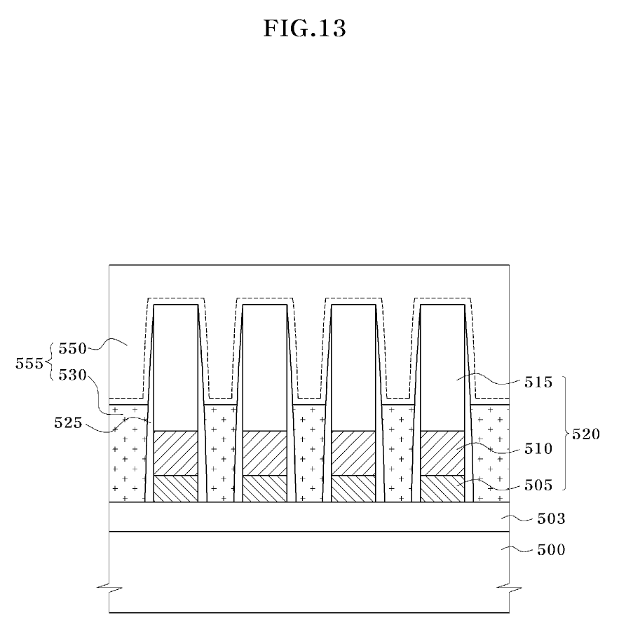

Referring to FIGS. 13 and 14, the exposed portion of the bit line stack 520 is covered with a second HDP oxide layer 550 by repeating the process of depositing the HDP oxide layer and the process of etching the overhang. This method can improve the gap-fill characteristic by removing the overhang formed on the top portion of the bit line stack 520, which hinders the complete filling of the gap between the bit line stacks 520, and repeating the deposition process. The process of depositing the HDP oxide layer filling the gaps of the bit line stacks 520 and the process of etching the overhang may be repeated for 4 cycles to 6 cycles. An interlayer dielectric 555 including the fluid dielectric 530 and the second HDP oxide layer 550 is formed by planarizing the second HDP oxide layer 550. The temperature of the semiconductor substrate 500 is adjusted below 350° C. by performing a cooling process using helium (He) gas on the back side of the semiconductor substrate 500, while depositing the seed layer (535 in FIG. 10) through the second HDP oxide layer 550. If the deposition process and the etching process are performed while maintaining the temperature of the semiconductor substrate 500 below 350° C., damage to the lower gate dielectric due to the high-temperature plasma can be prevented. The processing including the preheating process to the process of forming the interlayer dielectric 555 may be performed in-situ within a single chamber.

The above-described method can improve the gap-fill characteristic of the interlayer dielectric filling the gap between the bit line stacks by controlling the HDP process, which will be described below with reference to the attached drawings.

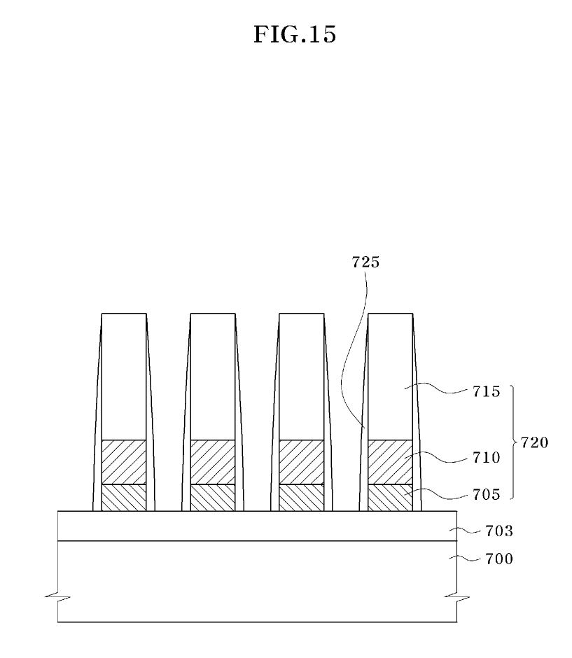

FIGS. 15 to 25 illustrate a method for fabricating an interlayer dielectric of a semiconductor device according to another embodiment of the present invention.

Referring to FIG. 15, bit line stacks 720 are formed on a semiconductor substrate 700. An interlayer dielectric 703 having a lower structure (not shown) with a word line is formed on the semiconductor substrate 700. The bit line stacks 720 include barrier metal patterns 705, bit line conductive patterns 710, and hard mask patterns 715. Bit line spacers 725 are formed on sidewalls of the bit line stacks 720.

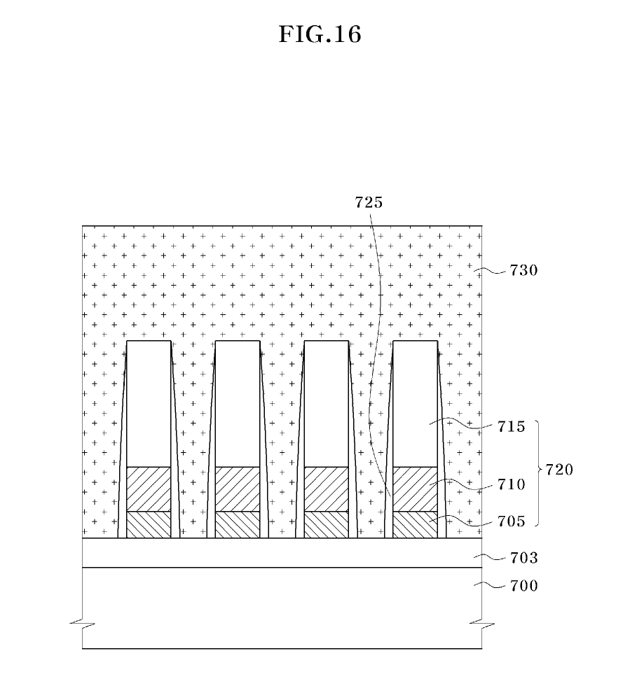

Referring to FIG. 16, a fluid dielectric 730 covering the bit line stacks 720 is formed on the semiconductor substrate 700. The fluid dielectric 730 is formed of SOD, for example, a PSZ compound. The semiconductor substrate 700 is heated at approximately 130° C. to approximately 150° C. for approximately 150 seconds to approximately 200 seconds, thereby evaporating a solvent from the fluid dielectric 730. The fluid dielectric 730 is changed into an oxide layer by performing a curing process on the fluid dielectric 730. The curing process is performed for approximately 1 hour while supplying 1 L hydrogen (H₂) gas and 2 L oxygen (O₂) at a temperature of approximately 450° C. to approximately 550° C. The fluid dielectric 730 is planarized by a planarization process, so that its surface is uniformly polished. The planarization process is performed until the fluid dielectric 730 has a thickness of 450 Å to 550 Å from the hard mask pattern 715 of the bit line stack 720.

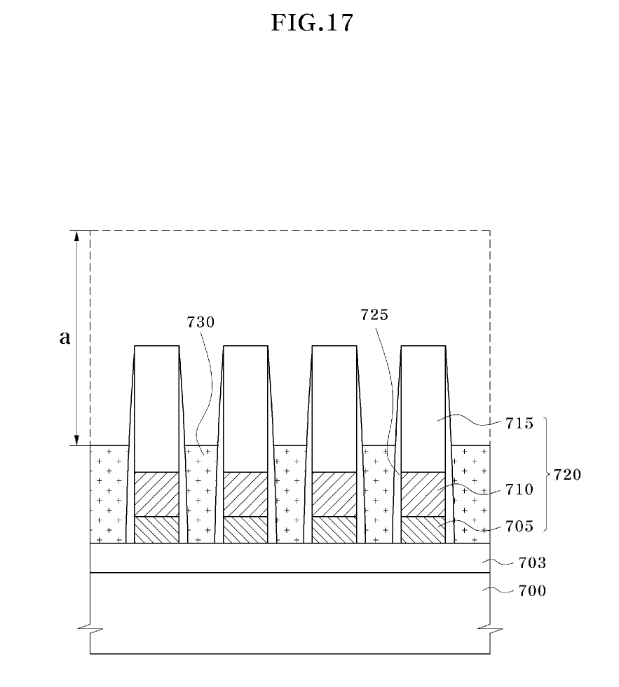

Referring to FIG. 17, the fluid dielectric 730 is recessed to expose a portion of the side surface of the bit line spacer 725 of the bit line stack 720. The process of recessing the fluid dielectric 730 is performed using a hydrogen fluoride (HF) aqueous solution in which water (H₂O) and hydrogen fluoride (HF) are mixed at a volume ratio of 100:1. The fluid dielectric 730 is recessed to a predetermined depth (a) from the top surface of the fluid dielectric 730, for example a thickness of approximately 900 Å to approximately 1,100 Å, so that a portion of the side surface of the bit line spacer 725 of the bit line stack 720 is exposed.

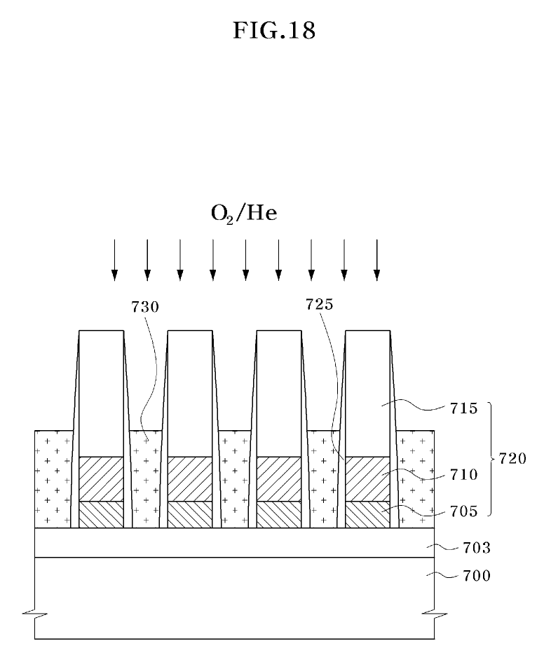

Referring to FIGS. 18 and 14, the semiconductor substrate 700 is preheated in an atmosphere containing oxygen (O₂) gas and helium (He) gas. Specifically, the semiconductor substrate 700 is loaded onto a stage 605 of an HDP chamber 600 as illustrated in FIG. 14. Oxygen (O₂) gas and argon (Ar) gas are supplied as a source gas from a gas tank 610 to the HDP chamber 600 through gas supply nozzles 615 and 617, and helium (He) gas is supplied as an additive gas. In addition, power is supplied and preheating is performed for 20-25 seconds. The oxygen (O₂) gas is supplied at a flow rate of approximately 50 sccm to approximately 150 sccm, the argon (Ar) gas is supplied at a flow rate of approximately 40 sccm to approximately 50 sccm, and the helium (He) gas is supplied at a flow rate of approximately 200 sccm to approximately 300 sccm. The helium (He) gas is additionally supplied from the top 615 of the HDP chamber 600 at a flow rate of approximately 200 sccm to approximately 300 sccm. As the source power for generating plasma, a top bias 625 of approximately 4,500 W to approximately 5,500 W is supplied, and a side bias 630 of approximately 3,500 W to approximately 4,500 W is supplied. However, a bottom bias 635 is not supplied.

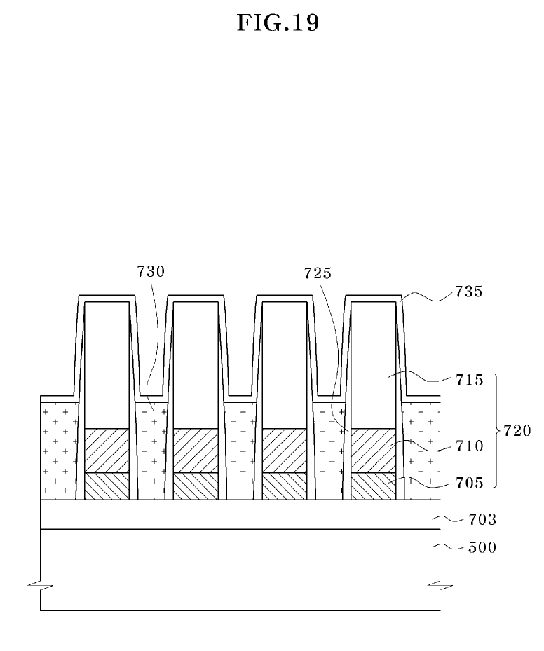

Referring to FIGS. 19 to 14, a seed layer 735 is formed on the exposed portions of the recessed fluid dielectric 730 and the exposed spacer layer 725. An HDP deposition source is supplied within the HDP chamber 600 where the preheating is performed. The HDP deposition source includes oxygen (O₂) gas, silane (SiH₄) gas, and helium (He) gas. The oxygen (O₂) gas as the HDP deposition source is supplied at a flow rate of approximately 100 to approximately 120 sccm. In addition, the silane (SiH₄) gas is supplied from the top 615 of the HDP chamber 600 at a flow rate of approximately 25 sccm to approximately 35 sccm and is supplied from the side 617 of the HDP chamber 600 at a flow rate of approximately 40 sccm to approximately 55 sccm. The helium (He) gas is supplied from the top 615 of the HDP chamber 600 at a flow rate of approximately 50 sccm to approximately 150 sccm and is supplied from the side 617 of the HDP chamber 600 at a flow rate of approximately 150 sccm to approximately 250 sccm. In this case, in order to generate plasma, the top bias 625 of approximately 7,500 W to approximately 8,500 W is supplied, and the side bias 630 of approximately 4,500 W to approximately 5,500 W is supplied. In addition, the bottom bias 635 of approximately 450 W to approximately 500 W is supplied from the bottom of the HDP chamber 600. Due to the HDP deposition source and the biases supplied to the HDP chamber 600, the seed layer 735 is formed to a thickness of approximately 100 Å to approximately 200 Å on the exposed portions of the recessed fluid dielectric 730 and the spacer layer 725 of the bit line stack 720.

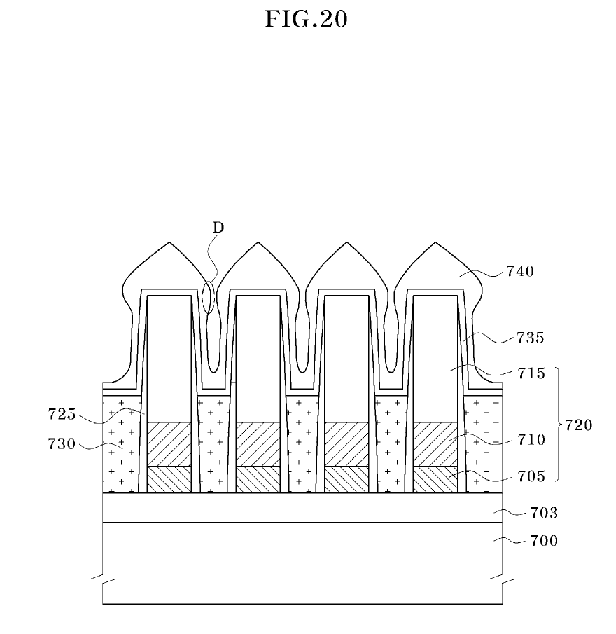

Referring to FIGS. 20 and 14, a first HDP oxide layer 740 is formed on the seed layer 735 by additionally supplying the HDP deposition source. Specifically, the HDP deposition source including oxygen (O₂) gas, silane (SiH₄) gas, and helium (He) gas is supplied within the HDP chamber 600. The oxygen (O₂) gas is supplied at a flow rate of approximately 50 sccm to approximately 60 sccm. The silane (SiH₄) gas is supplied from the side 617 of the HDP chamber 600 at a flow rate of approximately 20 sccm to approximately 30 and is supplied from the top 615 of the HDP chamber 600 at a flow rate of approximately 10 sccm to approximately 20 sccm. In addition, the helium (He) gas is supplied from the side 617 of the HDP chamber 600 at a flow rate of approximately 150 sccm to approximately 250 sccm and is supplied from the top 615 of the HDP chamber 600 at a flow rate of approximately 50 sccm to approximately 150 sccm. The top bias 625 of approximately 6,500 W to approximately 7,500 W is supplied, and the side bias 630 of approximately 6,500 W to approximately 7,500 W is supplied. In addition, the bottom bias 635 of approximately 1,500 W to approximately 2,500 W is supplied from the bottom of the HDP chamber 600. Thus, the first HDP oxide layer 740 is formed on the seed layer 735 to a thickness of approximately 150 Å to approximately 250 Å. In this case, due to a narrow gap between the bit line stacks 720, the deposition is quickly performed on the top portion, thereby forming an overhang D.

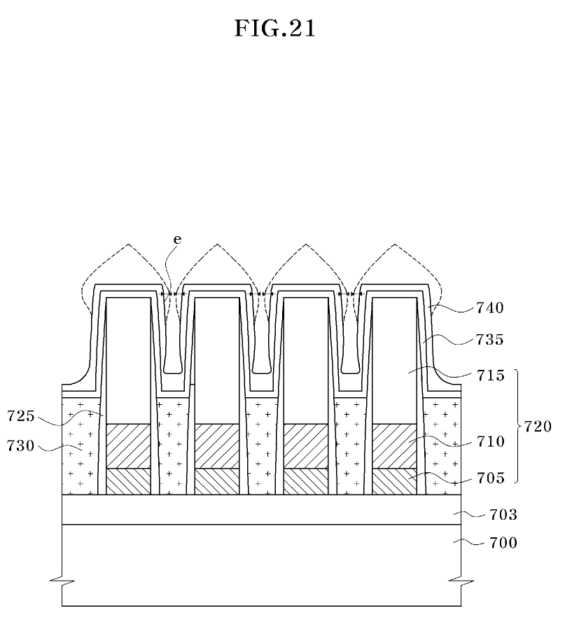

Referring to FIGS. 21 and 14, the overhang (D in FIG. 20) formed on the top portion of the bit line stack 720 is etched by supplying an etching gas to the first HDP oxide layer 740. Specifically, the etching gas uses fluorine (F) based gas, for example, nitrogen trifluoride (NF₃) gas, and helium (He) gas. In addition, power is supplied to the HDP chamber 600. The nitrogen trifluoride (NF₃) is supplied at a flow rate of approximately 100 sccm to approximately 150 sccm, and the helium (He) gas is supplied at a flow rate of approximately 150 sccm to approximately 250 sccm. As the source power for generating etching plasma, the top bias 625 of approximately 1,500 W to approximately 2,500 W is supplied from the top 615 of the HDP chamber 600, and the side bias 630 of approximately 4,000 W to approximately 6,000 W is supplied from the side 617 of the HDP chamber 600. The etching process is performed while adjusting an etch target (e) to a thickness of approximately 35 Å to approximately 45 Å. While forming the first HDP oxide layer 740, the overhang formed on the top portion of the bit line stack 720 is etched, thereby securing a deposition space.

The overhang etching process etches the protruding portion of the first HDP oxide layer 740 to a predetermined thickness to remove the overhang (D in FIG. 20) formed on the top portion of the bit line stack 720, thereby making it easy to perform the gap-fill process. If the side bias 630 is higher than the top bias 625 or the bottom bias 635, the side of the first HDP oxide layer 740 is deeply etched.

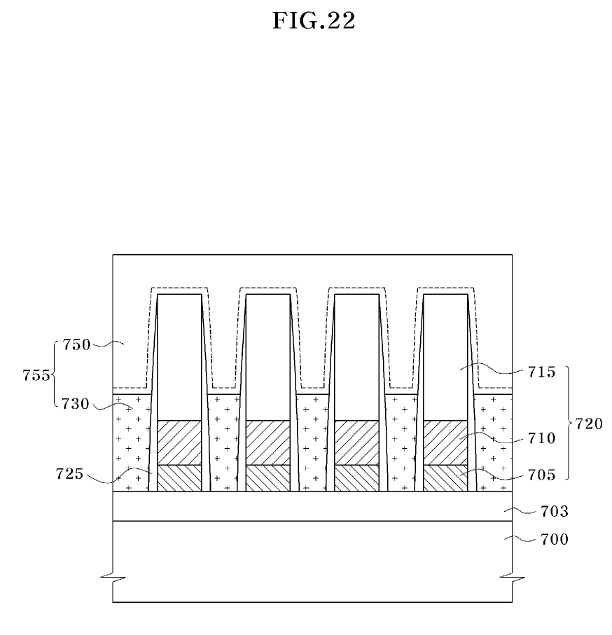

Referring to FIGS. 22 and 14, a second HDP oxide layer 750 covering the bit line stack 720 is formed by additionally performing the process of forming the HDP oxide layer and the process of etching the overhang. An interlayer dielectric 755 including the fluid dielectric 730 and the second HDP oxide layer 750 is formed by planarizing the second HDP oxide layer 750. The process of depositing the HDP oxide layer and the process of etching the overhang may be repeated for at least 10 cycles. The interlayer dielectric 755 includes the fluid dielectric 730 and the second HDP oxide layer 750. The fluid dielectric 730 fills a portion of a narrow gap between the bit line stacks 720, and the second HDP oxide layer 750 fills the other portion. The second HDP oxide layer 750 is harder than the fluid dielectric 730.

The interlayer dielectric 755 can further improve the gap-fill characteristic by adjusting the flow rate of the HDP deposition source or the etching gas and by adjusting the number of times that the deposition process and the etching process are performed. Specifically, the deposition thickness and the etching thickness are reduced by reducing the flow rate of the HDP deposition source and the etching gas, but the gap-fill characteristic is improved by increasing the number times that the deposition process and the etching process are performed. For example, after forming the first HDP oxide layer having a thickness of 700 Å by increasing the flow rate of the HDP deposition source, the overhang etching process is performed using the etch target of 190 Å, while supplying the etching source. The second HDP oxide layer covering the bit line stacks 720 can be formed by performing the deposition process and the overhang etching process for as many as 6 cycles. If the overhang etching process is performed using the etching target of 40 Å, while supplying the etching source, after forming the first HDP oxide layer of 200 Å by reducing the flow rate of the HDP deposition source, the second HDP oxide layer can be formed by performing the overhang etching process for as many as 10 cycles. That is, by increasing the flow rates of the deposition source and the etching source, the number of additional cycles is reduced to shorten the fabrication process time. The gap-fill characteristic can be further improved by reducing the flow rates of the deposition source and the etching source and by increasing the number of additional cycles.

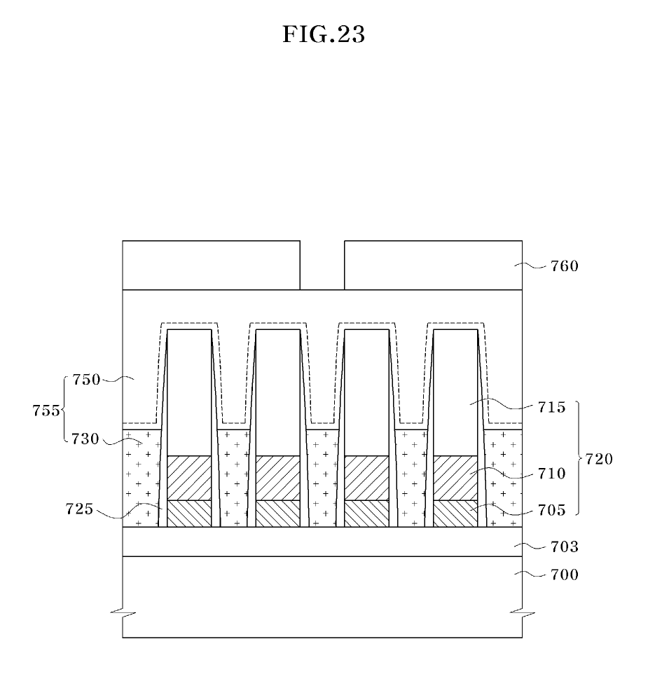

Referring to FIG. 23, a hard mask pattern 760 is formed on the interlayer dielectric 755. The hard mask pattern 760 defines a region where a storage node contact hole is to be formed. The hard mask pattern 760 may be formed of amorphous carbon. The amorphous carbon layer is generally deposited at a high temperature of more than 550° C. If the interlayer dielectric is formed of a single-layered fluid dielectric, a crack occurs during the process of forming the amorphous carbon layer, causing a bunker defect. However, if the interlayer dielectric 755 has a dual-layered structure including the fluid dielectric 730 and the second HDP oxide layer 750, the second HDP oxide layer 750 that is harder than the fluid dielectric 730 can support the bit line stacks 720 even during a high-temperature terminal treatment, thereby preventing the occurrence of a crack.

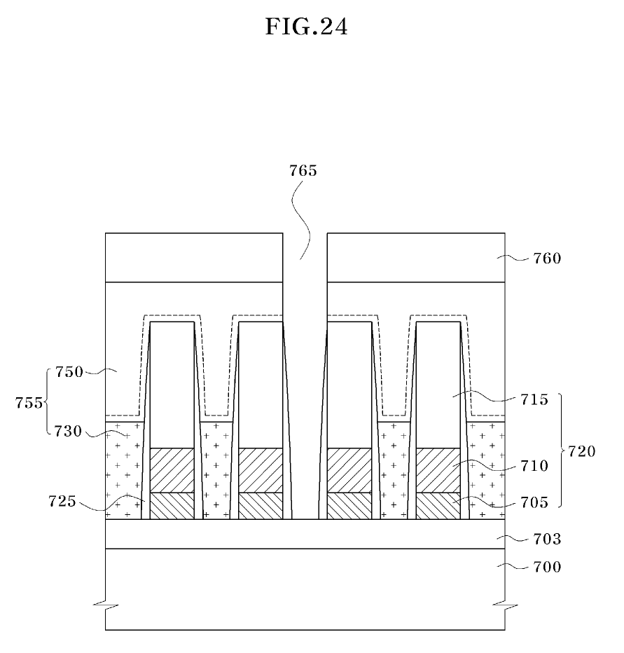

Referring to FIG. 24, a storage node contact hole 765 is formed between the bit line stacks 720 by etching the exposed portion of the interlayer dielectric 755 using the hard mask pattern 760 as a mask. The hard mask pattern 760 is then removed.

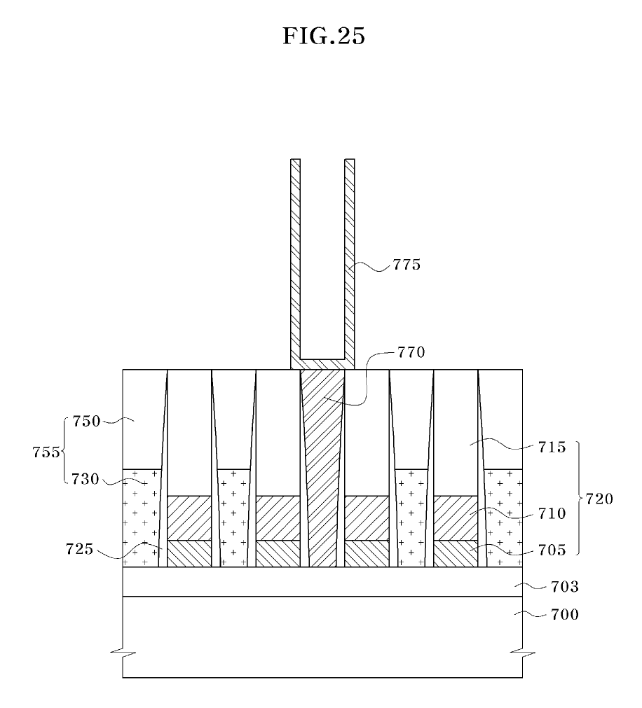

Referring to FIG. 25, a storage node contact plug 770 is formed between the bit line stacks 720. Specifically, a semiconductor layer, for example a polysilicon layer, is formed on the interlayer dielectric 755. Then, the storage node contact plug 770 is formed by performing a separating process on the semiconductor layer. The separating process may be performed using a CMP process. A storage node metal layer 775 is formed on the storage node contact plug 775.

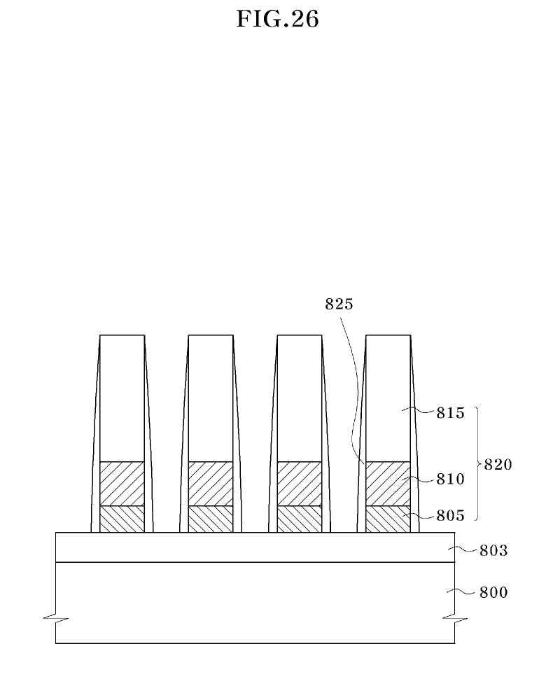

FIGS. 26 to 29 illustrate a method for fabricating an interlayer dielectric of a semiconductor device according to still another embodiment of the present invention.

Referring to FIG. 26, bit line stacks 820 are formed on a semiconductor substrate 800. An interlayer dielectric 803 having a lower structure (not shown) with a word line is formed on the semiconductor substrate 800. The bit line stacks 820 include barrier metal patterns 805, bit line conductive patterns 810, and hard mask patterns 815. Bit line spacers 825 are formed on sidewalls of the bit line stacks 820.

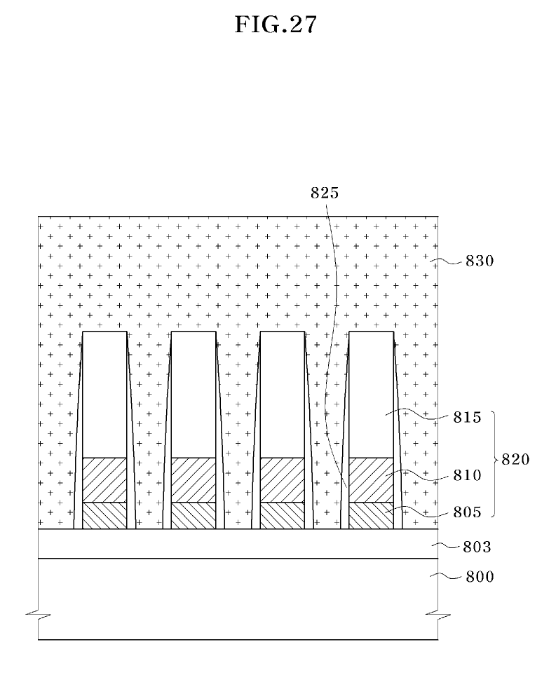

Referring to FIG. 27, a fluid dielectric 830 covering the bit line stacks 820 is formed. The fluid dielectric 830 may be formed by spin-coating SOD, for example, a PSZ compound. The semiconductor substrate 800 is heated at approximately 130° C. to approximately 150° C. for approximately 150 seconds to approximately 200 seconds, thereby evaporating a solvent from the fluid dielectric 830. The fluid dielectric 830 is changed into an oxide layer by performing a curing process on the fluid dielectric 830. The curing process is performed for approximately 1 hour while supplying 1 L hydrogen (H₂) gas and 2 L oxygen (O₂) at a temperature of approximately 450° C. to approximately 550° C. The fluid dielectric 830 is planarized by a planarization process, so that its surface is uniformly polished.

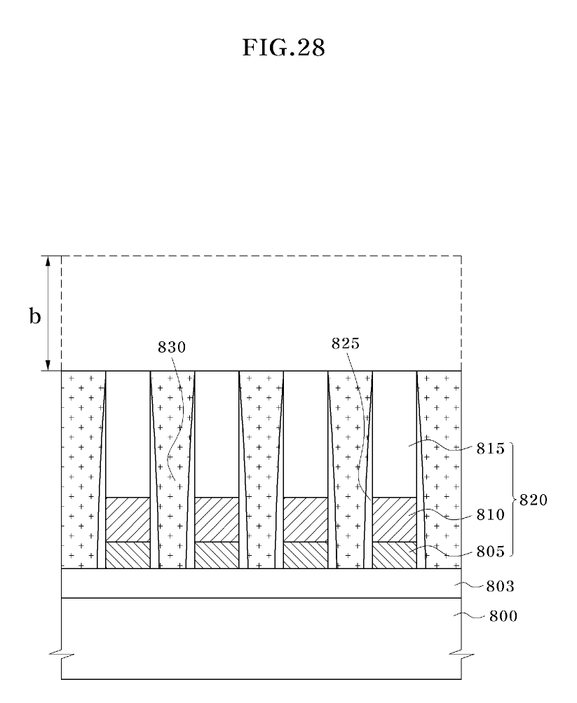

Referring to FIG. 28, the fluid dielectric 830 is recessed to a predetermined depth (b) to expose a portion of the top surface of the hard mask patterns 815. The process of recessing the fluid dielectric 830 is performed using a hydrogen fluoride (HF) aqueous solution in which water (H₂O) and hydrogen fluoride (HF) are mixed at a volume ratio of 100:1. The recessing process is stopped when the surfaces of the hard mask patterns 815 are exposed.

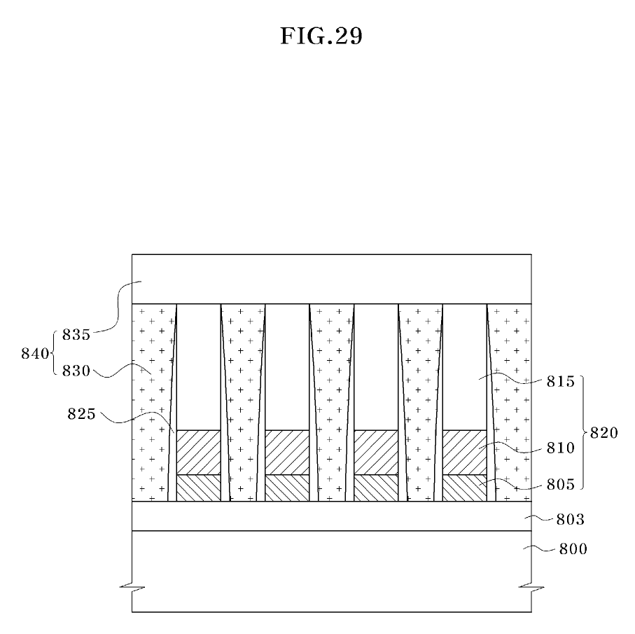

Referring to FIG. 29, a capping layer 835 is formed on the fluid dielectric 830 and the hard mask patterns 815. The forming of the capping layer 835 may include: loading the semiconductor substrate 800 within the HDP chamber 600 of FIG. 14; forming a seed layer (not shown) by supplying an HDP deposition source and power to the HDP chamber; and additionally supplying the HDP deposition source. The HDP deposition source includes oxygen (O₂) gas, silane (SiH₄) gas, and helium (He) gas. In this way, an interlayer dielectric 840 is formed. The interlayer dielectric 840 includes the fluid dielectric 830 and the capping layer 835 formed by the HDP process. The fluid dielectric 830 has an excellent gap-fill characteristic and fills spaces between the bit line stacks 820. The capping layer 835 is harder than the fluid dielectric 830 and is formed on the fluid dielectric 830 and the bit line stacks 820. Therefore, the capping layer 835 can prevent a crack from occurring on the fluid dielectric 830 even during a subsequent thermal treatment.

According to the present invention, the interlayer dielectric filling gaps between the bit line stacks has a dual-layered structure including the fluid dielectric at the lower portion, and the oxide layer formed using the HDP process at the upper portion. The interlayer dielectric is formed with the dual layer of the fluid dielectric or the oxide layer using the HDP process, instead of a single layer. In particular, the oxide layer that is formed by the HDP process and is harder than the fluid dielectric that is formed at the upper portion of the bit line stack. Therefore, the oxide layer that is harder than the fluid dielectric supports and fixes the bit line stack on both sides, thereby preventing bending of the bit line stack. In addition, in order to prevent the degradation of the gap-fill characteristic due to the height of the bit line stack, an aspect ratio is reduced by filling a portion of the gap between the bit line stacks with the fluid dielectric, and the other portion is filled with the oxide layer formed using the HDP process. In this way, a sufficient gap-fill margin can be ensured. The oxide layer formed using the HDP process has a stress substantially equal to the typical HDP oxide layer and its etching rate is relatively slower than the fluid dielectric having a fast etching rate. Therefore, it is possible to prevent the bunker defect caused by the penetration of the chemical solution due to misalignment. Furthermore, the gap-fill characteristic can be adjusted by controlling the HDP deposition process and the overhang etching process during the process of forming the oxide layer using the HDP process.

While the present invention has been described with respect to the specific embodiments, it will be apparent to those skilled in the art that various changes and modifications may be made without departing from the spirit and scope of the invention as defined in the following claims.

What is claimed is:

1. A method for fabricating an interlayer dielectric in a semiconductor device, the method comprising:
forming a conductive pattern over a semiconductor substrate;
forming a fluid dielectric over the conductive pattern and the semiconductor substrate to fill gaps of the conductive pattern;
etching the fluid dielectric to expose the conductive pattern; and
depositing a buried dielectric on the conductive pattern exposed by the etching process, the buried dielectric layer being denser than the fluid dielectric, thereby forming an interlayer dielectric including the fluid dielectric and the buried dielectric.

2. The method of claim 1, further comprising planarizing the etched fluid dielectric by a chemical mechanical polishing (CMP) process.

3. The method of claim 1, wherein the fluid dielectric comprises a polysilazane (PSZ) based spin on dielectric (SOD).

4. The method of claim 1, wherein the fluid dielectric is etched until a portion of a sidewall of the conductive pattern is exposed.

5. The method of claim 1, wherein the depositing of the buried dielectric comprises:
depositing a seed layer over the fluid dielectric exposed by the etching process and a portion of a sidewall of the conductive pattern;
forming a high density plasma (HDP) oxide layer over the seed layer by supplying an HDP deposition source;
etching an overhang formed on a top portion of the bit line stack when forming the HDP oxide layer; and
burying the bit line stack to the buried dielectric by additionally performing the process of forming the HDP oxide layer and the process of etching the overhang.

6. The method of claim 5, wherein the HDP deposition source comprises silane (SiH₄) gas, oxygen (O₂) gas, and helium (He) gas.

7. The method of claim 5, wherein the overhang formed on the top portion of the bit line stack is etched using a fluorine (F) based etching gas including nitrogen trifluoride (NF₃) gas.

8. The method of claim 5, further comprising performing a preheating process before forming the seed layer.

9. The method of claim 8, wherein the performing of the preheating process comprises:
loading the semiconductor substrate within an HDP chamber; and
supplying oxygen (O₂) gas, argon (Ar) gas, and helium (He) gas and supplying bias to the top and side of the HDP chamber.

10. The method of claim 5, wherein the process of forming the HDP oxide layer and the process of etching the overhang are performed for 4-10 cycles.

11. The method of claim 1, wherein the buried dielectric prevents bending of the bit line stacks and fixes locations of the bit line stacks.

12. A method for fabricating an interlayer dielectric in a semiconductor device, the method comprising:
forming bit line stacks over a semiconductor substrate;
forming a fluid dielectric over the bit line stacks;
etching the fluid dielectric to expose a portion of sidewalls of the bit line stacks;
forming a seed layer over the fluid dielectric and the exposed portion of the sidewalls of the bit line stacks;
forming a first HDP oxide layer over the seed layer by supplying an HDP deposition source including silane (SiH₄) gas, oxygen (O₂) gas, and helium (He) gas;
etching an overhang formed on top portions of the bit line stacks by supplying an etching gas to the first HDP oxide layer; and
forming an interlayer dielectric including the fluid dielectric and a second HDP oxide layer, the second HDP oxide layer being formed to cover the bit lines stacks by performing the process of forming the first HDP oxide layer and the process of etching the overhang.

13. The method of claim 12, further comprising planarizing the etched fluid dielectric by a chemical mechanical polishing (CMP) process.

14. The method of claim 12, wherein the fluid dielectric comprises polysilazane (PSZ) based spin on dielectric (SOD).

15. The method of claim 12, wherein the etching gas comprises a fluorine (F) based gas including nitrogen trifluoride (NF₃) gas.

16. The method of claim 12, wherein the process of forming the first HDP oxide layer and the process of etching the overhang are additionally performed for 4-10 cycles according to flow rates of the HDP deposition source and the etching gas.

17. The method of claim 12, wherein when flow rates of the HDP deposition source and the etching gas are reduced, the interlayer dielectric is formed by performing the process of forming the first HDP oxide layer and the process of etching the overhang for 6-10 cycles according to the flow rates.

18. The method of claim 12, wherein when flow rates of the HDP deposition source and the etching gas are increased, the interlayer dielectric is formed by additionally performing the process of forming the first HDP oxide layer and the process of etching the overhang for 4-6 cycles according to the flow rates.

19. The method of claim 12, wherein the second HDP oxide layer prevents bending of the bit line stacks and fixes locations of the bit line stacks.

20. A method for fabricating an interlayer dielectric in a semiconductor device, the method comprising:
forming bit line stacks over a semiconductor substrate;
forming a fluid dielectric over the bit line stacks;
planarizing the fluid dielectric to expose top surfaces of the bit line stacks; and
forming a capping layer over the bit line stacks and the fluid dielectric, the capping layer being denser than the fluid dielectric.

21. The method of claim 20, wherein planarizing the fluid dielectric comprises a chemical mechanical polishing (CMP) process.

22. The method of claim 20, wherein the fluid dielectric comprises a polysilazane (PSZ) based spin on dielectric (SOD).

23. The method of claim 20, wherein the forming of the capping layer comprises:
forming a seed layer by supplying an HDP deposition source to the exposed top surfaces of the bit line stacks; and
forming the capping layer over the fluid dielectric and the bit line stacks by supplying the HDP deposition source to the seed layer.

24. The method of claim 23, wherein the HDP deposition source comprises silane (SiH₄) gas, oxygen (O₂) gas, and helium (He) gas.

25. The method of claim 20, wherein the capping layer prevents bending of the bit line stacks and fixes locations of the bit line stacks.
